(19) United States
(12) Patent Application Publication
(10) Pub. No.: US 2009/0236692 A1
(43) Pub. Date: Sep. 24, 2009

(54) RC FILTERING DEVICE HAVING AIR GAP CONSTRUCTION FOR OVER VOLTAGE PROTECTION

(76) Inventors: Sheng-Fu Su, Luzhu Shiang (TW); Hui-Ming Feng, Jhongli City (TW); Yi-Lin Wu, Pingtung City (TW)

Correspondence Address: LOWE HAUPTMAN HAM & BERNER, LLP, 1700 DIAGONAL ROAD, SUITE 300, ALEXANDRIA, VA, 22314, US

(21) Appl. No.: 12/053,699

(22) Filed: Mar. 24, 2008

(51) Int. Cl. H01L 29/00

(52) U.S. Cl. 257/533; 257/E29.001

(57) ABSTRACT

The present invention relates to a RC filtering device, consists of: a lower substrate, a first intermediate substrate, a second intermediate substrate and an upper substrate. On top surface of the lower substrate is a cross form electrode layer. At both ends of the electrode layer in one direction forms a pair of air gaps to function as over voltage protection. The first intermediate substrate is formed above the lower substrate also has a pair of grooves corresponding to said air gaps, and on the top surface of the second intermediate layer, there is a transmission wire. The said transmission wire is formed with metallic layer at its both ends and the metallic oxide layer made with electrical resistance, this transmission wire and the electrode layer on the lower substrate form an RC filtering device.

### BACKGROUND OF THE INVENTION

1. Field of the Invention

The present invention relates to an RC filtering device, specifically to an RC filtering device that has air gap construction for over voltage protection.

2. Description of Prior Art

It is known to public that today's electronic device is focusing on speed of signal transferring, for example, signal frequency of HDMI has reached 742.5 MHz, its electrostatic discharge (ESD) demand for better over voltage protection device is higher than before, with low capacitance, such over voltage protection device can avoid high frequency signal from reducing in high speed transmission.

Moreover, the noise of electromagnetic wave in the atmosphere is coupled to the circuit via coupling function, that causes misjudgment of signal from IC, therefore, the combination of filtering and over voltage protection for signals on high speed transmission line is very important.

### SUMMARY OF THE INVENTION

Therefore, the object of present invention is to provide an RC filtering device having an air gap construction for over voltage protection, it consists constructions of RC filtering and over voltage protection structure that has air gap construction, so as to solve the dual problems of electrostatic discharge (ESD) and electromagnetic interference (EMI) faced by signal during high speed transmission.

According to the RC filtering device having an air gap construction for over voltage protection of present invention, it consists of: a lower substrate, an electrode layer formed on the top surface of the said lower substrate, this electrode layer is formed by a cross electrode. Wherein, one of the electrode in an orientation has two grooves at both end portions, the said grooves cut through the electrode layer and extend into the interior of lower substrate; an intermediate substrate, on the substrate is a second pair of grooves, the second pair of grooves correspond in location with the grooves formed in the lower substrate, and the second pair of grooves have the same length and width as the grooves formed in the lower substrate; a second intermediate substrate, its top surface contains a transmission wire, the said transmission wire lays in the same direction as the lower substrate electrode layer having the grooves; and an upper substrate that is put onto top of the said second intermediate substrate.

A more complete understanding of these and other features and advantages of the present invention will become apparent from a careful consideration of the following detailed description of certain embodiments illustrated in the accompanying drawings.

### BRIEF DESCRIPTION OF THE DRAWINGS

FIG. 1 is a decomposited three-dimensional view showing the structure of RC filtering device having air gap construction for over voltage protection of present invention.

FIG. 2 is a cross-sectional view showing the RC filtering device having air gap construction for over voltage protection of present invention.

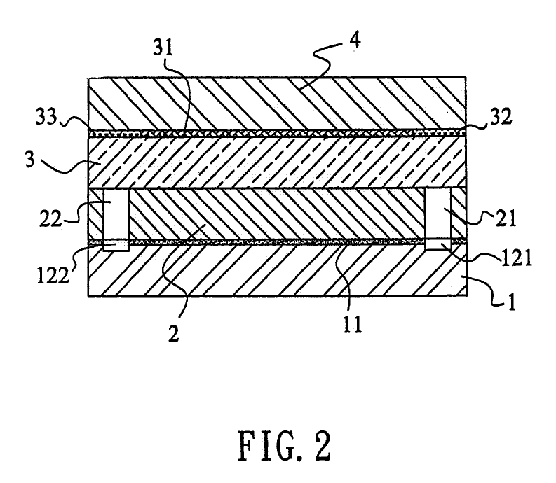

FIG. 3 is a three-dimensional view showing the RC filtering device having air gap construction for over voltage protection of present invention.

FIG. 4 is an equivalent electric circuit of the RC filtering device of present invention.

### DETAILED DESCRIPTION OF THE PREFERRED EMBODIMENTS

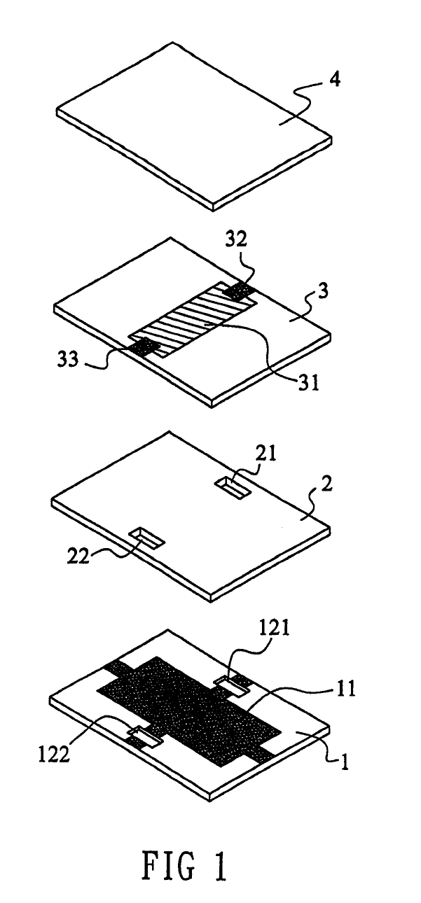

As shown in FIGS. 1 & 2, the RC filtering device having air gap construction for over voltage protection of present invention consists of: a lower substrate 1, a first intermediate substrate 2, a second intermediate substrate 3 and an upper substrate 4. An electrode layer 11 is formed on the top surface of the lower substrate 1, the electrode layer 11 is formed in cross shape, one of the electrode layer in one orientations forms a pair of groove 121, 122 at its end portions, the said first pair of grooves 121, 122 not only cut through the electrode layer 11, but also cut into the interior of lower substrate 1;

the first intermediate substrate 2 is formed on the lower substrate, at the position corresponding to the said grooves 121, 122 formed on the lower substrate 1, the first intermediate substrate 2 forms a second pair of grooves 21, 22, and the second pair of grooves 21, 22 cuts through the first intermediate substrate 2. The second pair of grooves 21, 22 not only correspond to said first pair of grooves 121, 122 in position, they also have the same length and width as said first pair of grooves 121, 122.

Referring to FIGS. 1 & 2 again, a second intermediate substrate 3 is formed on the top surface of said first intermediate substrate 2, and an transmission wire 31 is formed on the upper surface of the second intermediate substrate 3, both ends of the transmission wire 31 have electrode layers 32, 33, the transmission wire 31 between the said electrode layer 32, 33 can be a metallic oxide layer, the metallic oxide layer is made up with material having electric resistance; the orientation of said transmission wire 31 is same as the electrode formed on the lower substrate having said grooves 121, 122.

An upper substrate 4, is formed on the upper surface of the second intermediate substrate 3.

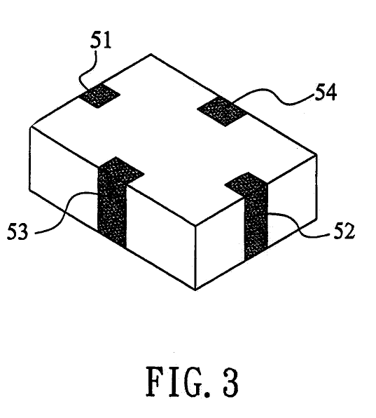

As shown in FIG. 3, after the lower substrate 1, the first intermediate substrate 2, the second intermediate substrate 3 and the upper substrate 4 are put together in order. The terminal electrodes 51, 52, 53, 54 are respectively formed at the four sides of the body, wherein, the terminal electrodes 51, 52 are formed as ground terminals, and the terminal electrodes 53, 54 are respectively formed as input terminal and output terminal.

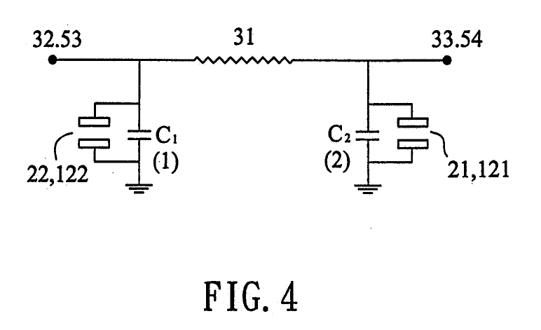

The electric circuit equivalent to the RC device having air gap construction for over voltage protection is shown in FIG. 4. It is very clearly to see that the lower substrate 1 and the first intermediate substrate form a pair of capacitors C₁ & C₂, the air gaps 21, 22 & 121, 122 respectively forms an over voltage protection construction, the transmission wire 31 forms a resistor between the capacitors C₁ & C₂, while 32/53 and 33/54 are respectively forms input and output terminal.

Regarding to the materials for above mentioned RC filtering device having air gap construction for over voltage protection of present invention, its lower substrate 1, the first intermediate substrate 2, the second intermediate substrate 3 and the upper substrate 4 are formed by the insulate materials of aluminum compounds (such as alumina), titanium or silicon, etc. The RC filtering device having air gap construction for over voltage protection of present invention can also be formed in multi-layer thin film.

The aforesaid electrode layer 11 of lower substrate 1 and the transmission wire 31 of second intermediate substrate 3 can be formed of one of the following materials: gold, silver, palladium, platinum, wolfram or copper, and can be formed by any alloy of said metallic elements or any composite material of said metallic elements.

The said grooves 121, 122 and 21, 22 formed in the lower substrate 1 and the first intermediate substrate 2 can be made by cutting, after the substrates are put together in order, grooves 121, 122, 21, 22 together form an air gap to provide over voltage protection to electronic circuit. Also, in accordance to the needs and requirements, the size of the air gap can be adjusted, such as the depth and width, that would not be limited by production.

According to the above mentioned construction, RC filtering device can easily obtain the function of over voltage protection, it is easy in production and would have the electrical properties of RC filtering device.

In conclusion of the above, since the RC filtering device having an air gap construction for over voltage protection of present invention is not disclosed previously and it does not have been sold anywhere, therefore, it is believed to be an invention of novelty. Moreover, the unique character and ability of present invention are more advanced, it is then believed that the present invention is an invention with progressiveness, and meets the requirement of patent application according to relevant Patent Law.

Although the present invention has been described with a certain degree of particularity, the present disclosure has been made by way of example and changes in details of structure may be made without departing from the spirit thereof.

What is claimed is:

1. An RC filtering device having an air gap construction for over voltage protection, consisting of
a lower substrate, its top surface is formed with an electrode layer, the electrode layer in one direction has at least one groove that cuts through the electrode layer and extends into the interior of the lower substrate;
a first intermediate substrate, formed above the lower substrate, at the position corresponding to said grooves formed on the lower substrate, there is at least a groove cuts through the first intermediate substrate;
a second intermediate substrate, formed above the first intermediate board, on the top surface of the second intermediate substrate is formed with a transmission wire, both ends of said transmission wire have an electrode layer, said transmission wire is formed by a metallic oxide layer having electric resistance;
a covering board, formed above the second intermediate board; and
a plurality of terminal electrodes, formed on the side surfaces of the body of the device.

2. The RC filtering device having an air gap construction for over voltage protection as claimed in claim 1, wherein the said electrode layer formed on the top surface of said lower substrate is made from one of the following materials: gold, silver, palladium, platinum, wolfram or copper, and can be made from any alloy of combining one of the said metallic elements or any composite material of said metallic elements.

3. The RC filtering device having an air gap construction for over voltage protection as claimed in claim 1, wherein the said lower substrate, first intermediate substrate, second intermediate substrate and upper substrate are formed by an insulate material.

4. The RC filtering device having an air gap construction for over voltage protection as claimed in claim 3, wherein the said insulate material contains aluminum compound, titanium, or silicon.
